(19) United States
(12) Patent Application Publication
(10) Pub. No.: US 2025/0293218 A1
(43) Pub. Date: Sep. 18, 2025

(54) SEMICONDUCTOR PACKAGE HAVING AN INTEGRATED PASSIVE DEVICE THAT ACTS AS A SPACER

(71) Applicant: Sandisk Technologies, Inc., Milpitas, CA (US)

(72) Inventors: Chia-Hsuan Huang, Taichung (TW); Arkady Katz, Beer Sheva (IL); Han-Shiao Chen, Taichung (TW); Chien Te Chen, Taichung (TW); Pao-Yi Huang, Taichung (TW); Yu-Ying Tan, Taichung (TW); Shih-Chieh Chien, Taichung (TW); Chun Yan Koay, Penang (MY)

(21) Appl. No.: 18/606,010

(22) Filed: Mar. 15, 2024

(51) Int. Cl. H01L 25/16; H01L 23/00; H10B 80/00

(52) U.S. Cl. CPC H01L 25/16; H01L 24/32; H10B 80/00; H01L 24/33; H01L 24/48; H01L 24/49; H01L 24/73; H01L 2224/32145; H01L 2224/32265; H01L 2224/33181; H01L 2224/48091; H01L 2224/48227; H01L 2224/49175; H01L 2224/73215; H01L 2224/73265; H01L 2924/14511; H01L 2924/19011; H01L 2924/19103; H01L 2924/19105

(57) ABSTRACT

A semiconductor package includes an integrated passive device (IPD). The IPD includes at least one passive component and is positioned, sized and shaped to act as a spacer for the semiconductor package. The IPD can be a chip-scale package (CSP) IPD or a surface mount technology (SMT) IPD. Using the IPD as a spacer allows additional electronic components, such as memory dies, to be added to the semiconductor package, without increasing the overall size of the semiconductor package and without requiring the removal of passive components. As additional electronic components are added to the semiconductor package, the performance capabilities of the semiconductor package increases.

### BACKGROUND

Semiconductor packages, such as non-volatile memory devices, are widely used in various electronic devices such as cellular telephones, digital cameras, personal digital assistants, medical electronics, mobile computing devices, and non-mobile computing devices. As demand for semiconductor packages increase, so do the demands for higher capacity, smaller size and higher performance. However, it is increasingly difficult to reduce the size of a semiconductor package without sacrificing the capacity and/or capabilities of the semiconductor package.

For example, in order to increase the capacity of a non-volatile memory device, additional and/or larger memory dies are added to a stack of memory dies of the non-volatile memory device. However, as additional and/or larger memory dies are used, other components, such as passive components, may need to be removed from the non-volatile memory device. Removal of these components may negatively impact the performance of the non-volatile memory device.

Accordingly, it would be beneficial for a semiconductor package to have increased capacity and/or capabilities without removing other components.

### SUMMARY

The present disclosure describes a semiconductor package having an integrated passive device (IPD) that acts as a spacer. In an example, the IPD includes one or more passive components (e.g., resistors, capacitors, inductors) and is communicatively coupled to a printed circuit board (PCB) or a substrate of the semiconductor package. For example, the IPD is a chip-scale package (CSP) IPD and includes one or more connection points (e.g., solder balls) that are coupled to corresponding pads on the PCB. In another example, the IPD utilizes surface mount technology (SMT) and is communicatively coupled to corresponding pads on the PCB as part of a SMT process.

In an example, the IPD is positioned, shaped and/or sized in such a manner that the IPD is usable as a spacer in lieu of traditional spacers. Because the IPD includes various passive components, additional space on the PCB may be available when compared with current solutions (e.g., when compared with solutions in which an IPD is not used as a spacer). Additionally, due to the connection points utilized by the IPD (e.g., solder balls or other connection mechanisms), connection pads on the PCB may be smaller and/or more densely arranged when compared with current solutions, which may also free up additional space on the PCB.

Accordingly, examples of the present disclosure describe a semiconductor package that includes a PCB and an integrated circuit electrically coupled to the PCB. In an example, an IPD is also electrically coupled to the PCB. The semiconductor package also includes a stack of memory dies electrically coupled to the PCB. In an example, at least a portion of one memory die of the stack of memory dies is stacked on at least a portion of the IPD, which causes the IPD to act as a spacer.

Other examples of the present disclosure describe a data storage device that includes a PCB and an integrated circuit electrically coupled to the PCB. The data storage device also includes a stack of memory dies electrically coupled to the PCB. In an example, an IPD is also coupled to the PCB. In such examples, at least a portion of the IPD acts as a spacer and supports at least a portion of the stack of memory dies.

Still other examples of the present disclosure describe a semiconductor package that includes a PCB and an integrated circuit means coupled to the PCB. A spacing means is also coupled to the PCB. In an example, the spacing means includes at least one passive component. The semiconductor package also includes a stack of memory means coupled to the PCB. In an example, at least a portion of one memory means of the stack of memory means is coupled to at least a portion of the spacing means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates an integrated passive device (IPD) that is usable as a spacer in a semiconductor package according to an example.

FIG. 2 illustrates another integrated passive device (IPD) that is usable as a spacer in a semiconductor package according to an example.

FIG. 3A illustrates a top view of a semiconductor package having integrated passive devices (IPDs) that act as spacers according to an example.

FIG. 3B illustrates a side view of the semiconductor package of FIG. 3A according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

The demand for semiconductor packages, such as non-volatile memory devices, is increasing. However, as demand increases, so do the demands for higher capacity and higher performance, but in smaller packages. However, it is difficult to increase the capacity and/or performance of a non-volatile memory device while reducing the size of the overall package. For example, in order to increase capacity of the non-volatile memory device, additional memory dies are added to a stack of memory dies.

As additional memory dies are added, an amount of available space for other components, such as passive components, decreases. If these components are not included or are removed from the non-volatile memory device, the performance of the non-volatile memory device may be negatively impacted. Likewise, performance of the non-volatile memory device may also be negatively impacted if memory dies are removed from the stack of memory dies and/or if lower capacity memory dies are used.

To address the above, the present disclosure describes using an integrated passive device (IPD) as a spacer in a semiconductor package. In an example, the IPD includes one or more passive components, such as resistors, capacitors and/or inductors. The IPD is communicatively coupled to a printed circuit board (PCB) or a substrate of the semiconductor package.

In an example, the IPD is positioned near or proximate to an integrated circuit of the semiconductor package and is shaped and/or sized in such a manner that the IPD is usable as a spacer (e.g., in lieu or traditional/conventional spacers). For example, once the IPD is coupled to the PCB of the semiconductor package, one or more memory dies are stacked on a top surface of the IPD.

Because the IPD includes passive components, the passive components need not all be included on the PCB or substrate of the semiconductor package. As a result, larger or higher capacity memory dies may be used in the semiconductor package. In other examples, and because the IPD includes various passive components, additional space on the PCB is available when compared with current solutions (e.g., when compared with solutions in which traditional spacers are used). Additionally, due to the connection points utilized by the IPD (e.g., solder balls or other connection mechanisms), connection pads on the PCB may be smaller and/or more densely arranged when compared with current solutions, which may also free up additional space on the PCB.

Accordingly, many technical benefits may be realized including, but not limited to, increasing the capacity and/or capabilities of a semiconductor package without increasing a size of the semiconductor package, increasing a routing space of the semiconductor package which leads to increased electrical performance, improving molding compound flow thereby reducing the risk of memory dies cracking due to incomplete encasement of memory dies in the molding compound and increasing the overall reliability of the semiconductor package.

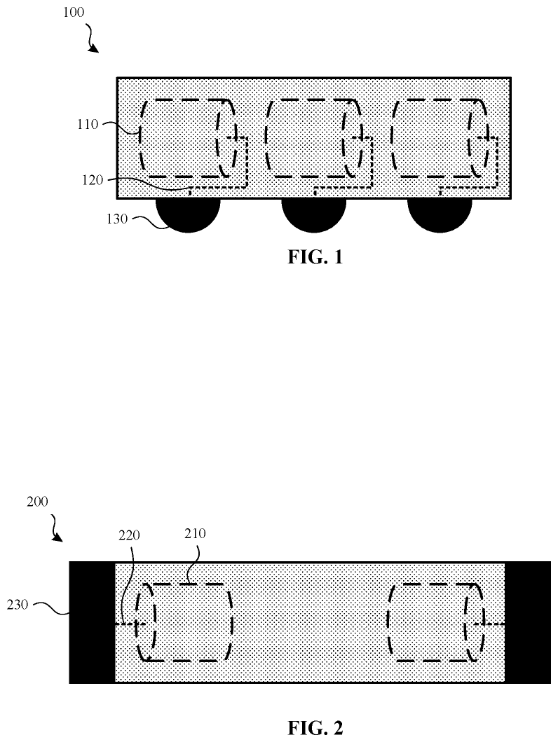

These benefits, along with other examples, will be shown and described in greater detail with respect to FIG. 1-FIG. 3B.

FIG. 1 illustrates an integrated passive device (IPD) 100 that is usable as a spacer in a semiconductor package according to an example. In an example, the IPD 100 includes one or more passive components 110. The passive components 110 include, but are not limited to, resistors, capacitors and/or inductors.

In an example, each passive component 110 includes a lead 120. The lead 120 electrically couples the passive component 110 to a connection point 130 of the IPD 100. In an example, the IPD is a chip-scale package (CSP) IPD. As such, the connection points 130 of the IPD 100 are solder balls. In an example, the solder balls are used to couple the IPD 100 to corresponding connection pads on a PCB or substrate of the semiconductor package.

In an example, the IPD 100 is shaped and/or sized to have one or more similar dimensions to other electronic components of the semiconductor package. For example, the IPD 100 has the same or a similar height as an integrated circuit of the semiconductor package. In another example a width and/or length of the IPD 100 is similar to, larger than or smaller than, a width and/or length of a memory die that is included in the semiconductor package. As such, the IPD 100 acts as, or is usable as, a spacer in the semiconductor package.

For example, when memory dies are added to the semiconductor package, a bottom surface of at least one memory die (or a die attach film (DAF) of at least one memory die) is stacked on a top surface of the IPD 100. As such, the IPD 100 provides support for, and enhances the mechanical strength of, the stack of memory dies. In an example, the IPD 100 also includes heat conductive material that dissipates heat from the memory dies in the stack. In another example, dummy bonding pads are provided on a top surface of the IPD 100. For example, a redistribution layer (RDL) is used to create or form at least part of the dummy bonding pads which may act or otherwise provide wire jump functionality to reduce wire sweeping.

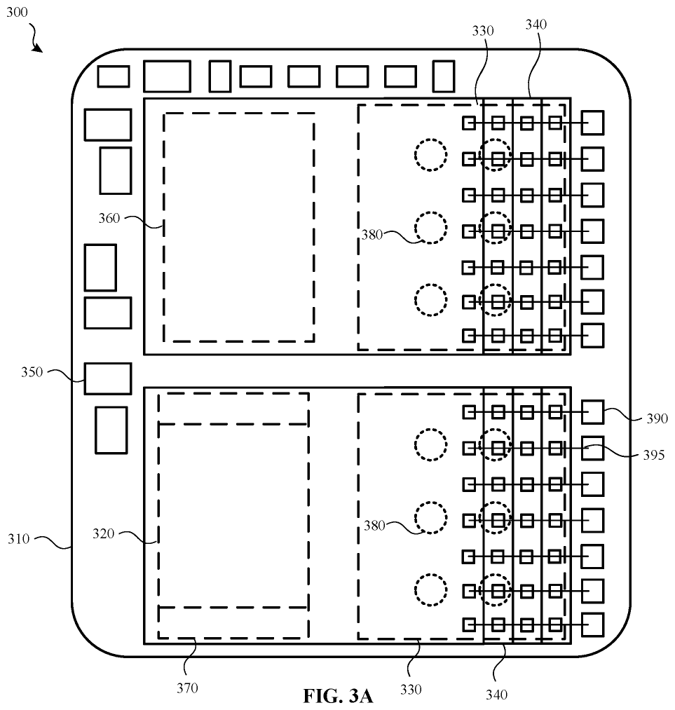

FIG. 2 illustrates another integrated passive device (IPD) 200 that is usable as a spacer in a semiconductor package according to an example. Like the IPD 100 shown and described with respect to FIG. 1, the IPD 200 includes one or more passive components 210. The passive components 210 include, but are not limited to, resistors, capacitors and/or inductors.

In an example, each passive component 210 includes a lead 220. The lead 220 electrically couples the passive component 210 to a connection point 230 of the IPD 200. In an example, the IPD is a surface mount technology (SMT) IPD. As such, the connection points 230 of the IPD 200 are metal leads or contacts. In an example, the connection points 230 of the IPD 200 are used to couple the IPD 200 to one or more connection pads on a PCB or substrate of the semiconductor package. Although metal leads or contacts are shown and described, solder balls may also be used to couple the IPD 200 to the PCB or substrate of the semiconductor package.

In an example, the IPD 200 is shaped and/or sized to have one or more similar dimensions to other electronic components of the semiconductor package. For example, the IPD 200 has the same or a similar height as an integrated circuit of the semiconductor package. In another example a width and/or length of the IPD 200 is similar to, larger than or smaller than, a width and/or length of a memory die that is included in the semiconductor package. As such, the IPD 200 acts as, or is usable as, a spacer in the semiconductor package.

For example, when memory dies are added to the semiconductor package, a bottom surface of at least one memory die (or a die attach film (DAF) of at least one memory die) is stacked on a top surface of the IPD 200. As such, the IPD 200 provides support for, and enhances the mechanical strength of, the stack of memory dies. In an example, the IPD 200 also includes heat conductive material that dissipates heat from the memory dies in the stack. In yet another example, the IPD 200 includes one or more transistors or silicon device that can be used as capacitors or for a capacitor implementation.

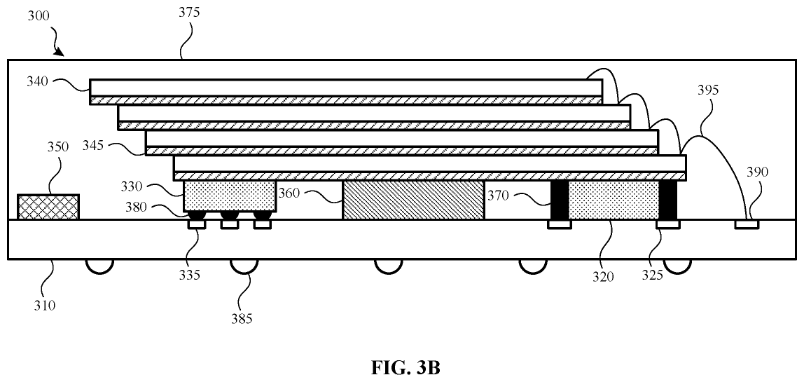

FIG. 3A illustrates a top view of a semiconductor package 300 having integrated passive devices (IPDs) that act as spacers according to an example. In an example, the IPDs shown and described with respect to FIG. 3A are similar to the IPD 100 and/or the IPD 200 shown and described with respect to FIG. 1 and FIG. 2 respectively.

In the example shown in FIG. 3A, the semiconductor package 300 includes multiple IPDs and multiple different types of IPDs. For example, the semiconductor package 300 includes at least one SMT IPD 320 and at least one CSP IPD 330. However, it is contemplated that the semiconductor package 300 can include multiple IPDs of the same type and/or a include single IPD. Additionally, it is contemplated that the semiconductor package 300 may include traditional spacers and IPDs that act as spacers.

In an example, a CSP IPD 330 is selected and used when additional routing space is desired. For example, CSP IPD 330 terminal pads may be smaller than SMT IPD 320 terminal pads. As a result, the additional routing space may be made available by selecting the CSP IPD 330 in lieu of the SMT IPD.

In another example, regardless of which IPD is selected and used, either type of IPD helps improve power integrity of the semiconductor package 300. For example, in current semiconductor packages, passive components are typically located far from a controller. However, the IPDs of the present disclosure bring passive components closer to the controller (e.g., the integrated circuit 360). As a result, parasitic parameters are reduced (when compared with current solutions) which improves power integrity of the semiconductor package 300 which leads to better performance.

In an example, the semiconductor package 300 includes a number of electronic components mounted on and/or electrically coupled to a PCB 310. For example, the semiconductor package 300 includes an integrated circuit 360 and/or various passive components 350. In an example, the integrated circuit 360 is a processor, a controller or other control circuitry.

As previously discussed, the semiconductor package 300 also includes a SMT IPD 320 and two CSP IPDs 330. In an example, the SMT IPD 320 and the CSP IPDs 330 are also electrically coupled to the PCB 310. For example, connection points 370 (e.g., metal leads) of the SMT IPD 320 are used to electrically couple the SMT IPD 320 to the PCB 310. Likewise, connection points 380 (e.g., solder balls) of the CSP IPDs 330 are used to electrically couple the CSP IPD 330 to the PCB 310. In an example, each of the IPDs are positioned adjacent, or proximate to, the integrated circuit 360.

The semiconductor package 300 also includes a number of memory dies 340. In an example, the memory dies 340 are NAND memory dies and are arranged in a stack. In the example shown in FIG. 3A, the semiconductor package 300 includes two stacks, and each stack includes four memory dies 340. Although four memory dies 340 are included in each stack, each stack may include fewer than four memory dies 340 or more than four memory dies 340. Additionally, the semiconductor package 300 can include more than two stacks of memory dies or fewer than two stacks of memory dies.

In an example, the memory dies 340 are electrically coupled to the PCB 310 using various bond pads 390 and bond wires 395. Additionally, the memory dies 340 are stacked on top of, or over, the IPDs. For example, a bottom surface of at least one memory die 340 is placed on a top surface of the CSP IPD 330 and/or a top surface of the SMT IPD 320. As such, the IPDs provide mechanical support for the memory dies 340. In an example, because the IPDs provide mechanical support for the memory dies, traditional/conventional spacers are not needed and/or included in the semiconductor package 300. However, in other examples, traditional spacers may be included as part of the stack of memory dies and/or underneath the stack of memory dies.

In an example, one or more dimensions of some, or all, of the IPDs are the same as, or similar to, one or more dimensions of the integrated circuit 360. For example, a height of the SMT IPD 320 and/or a height of the CSP IPDs 330 may be the same as, or similar to, a height of the integrated circuit 360. As such, when the memory dies 340 are included in the semiconductor package 300, a bottom surface of at least one memory die 340 contacts a top surface of the integrated circuit and/or a top surface of the IPDs. In another example, a width and/or a length of the SMT IPD 320 and/or of the CSP IPDs 330 are similar to a width and/or a length of the memory dies 340. As such, the IPDs can provide additional strength and/or support for the memory dies 340 in the stack.

In an example, using IPDs as spacers reduces, minimizes or eliminates the need for the memory dies 340 to overhang components 350 that are coupled to the PCB 310. As such, if/when a molding compound is added to the semiconductor package 300, the flow of the molding compound is less restricted (or not restricted) when compared with current solutions in which memory dies in a stack overhang components that are coupled to the PCB.

Additionally, because the passive components are coupled to respective connection points in each IPD, connection pads on the PCB 310 that are associated with the connection points of each IPD may be smaller and/or more arranged more densely when compared with current solutions. As a result, more routing space will be available on the PCB 310 when compared with current solutions in which most or all of the passive components are mounted directly on the PCB.

FIG. 3B illustrates a side view of the semiconductor package 300 of FIG. 3A according to an example. As previously discussed, in this example, the semiconductor package 300 includes multiple IPDs. For example, the semiconductor package 300 includes a SMT IPD 320 and a CSP IPD 330.

The SMT IPD 320 includes connection points 370 that electrically couple the SMT IPD 320 to corresponding bond pads 325 on the PCB 310. Likewise, the CSP IPD 330 includes connection points 380 that electrically couple the CSP IPD 330 to the corresponding bond pads 335 on the PCB 310. In an example, the bond pads 335 are shaped and/or sized to accommodate a first type of connection mechanism (e.g., solder balls) while the bond pads 325 are shaped and/or sized to accommodate a second type of connection mechanism (e.g., metal leads).

In an example, the SMT IPD 320 and the CSP IPD 330 are positioned on the PCB 310 to be adjacent and/or proximate to the integrated circuit 360. As shown in FIG. 3B, a height of each IPD is the same as, or similar to, a height of the integrated circuit 360. As such, each IPD may be used as a spacer (e.g., in lieu of a traditional spacer or a spacer that is used in current implementations) in the semiconductor package 300.

As previously discussed, the semiconductor package 300 also includes a number of memory dies 340 arranged in a stack. In an example, each memory die 340 includes or is otherwise associated with a die attach film (DAF) 345. The DAF 345 is used to bond at least a portion of one memory die 340 in the stack to another memory die 340 in the stack. The memory dies 340 are electrically coupled to the PCB 310 using various bond pads 390 and bond wires 395.

Additionally, the memory dies 340 are stacked on top of, or over, the IPDs. For example, the DAF 345 of at least one memory die 340 is placed on a top surface of the CSP IPD 330 and a top surface of the SMT IPD 320. Additionally, the DAF 345 of at least one of the memory dies 340 is placed on or over a top surface to the integrated circuit 360. As such, the IPDs and/or the integrated circuit 360, provide mechanical support for the memory dies 340.

As previously discussed, using IPDs as spacers, or having spacers act as IPDs, reduces, minimizes or eliminates the need for the memory dies 340 to overhang the components 350 that are coupled to the PCB 310. As such, if/when a molding compound is added to the semiconductor package 300, the flow of the molding compound is less restricted (or not restricted) when compared with current solutions in which memory dies overhang components that are coupled to the PCB.

In an example, the semiconductor package 300 includes one or more connection mechanisms 385 that enable the semiconductor package 300 to be communicatively coupled to another substrate or PCB. For example, the semiconductor package 300 may include solder balls or a ball grid array that enables the semiconductor package 300 to be surface mounted to a PCB or substrate. In such examples, the semiconductor package 300 may include a cover 375 or otherwise be at least partially enclosed in a housing. Although solder balls are shown and described, the semiconductor package 300 need not include solder balls. For example, the connection mechanisms 385 may be pins, gold finger contacts or other connection mechanisms 385 that enable the semiconductor package 300 to be removably coupled to a host device.

Although the disclosure describes an IPD acting as a spacer, it is also contemplated that a spacer may act as an IPD. For example, one or more passive components (and other circuitry) may be added to a spacer.

Examples of the present disclosure describe a semiconductor package, comprising: a printed circuit board (PCB); an integrated circuit electrically coupled to the PCB; an integrated passive device (IPD) electrically coupled to the PCB; and a stack of memory dies electrically coupled to the PCB, wherein at least a portion of one memory die of the stack of memory dies is stacked on at least a portion of the IPD causing the IPD to act as a spacer. In an example, the IPD is a chip-scale package (CSP) IPD. In an example, the IPD is a surface mount technology (SMT) IPD. In an example, the IPD is proximate to the integrated circuit. In an example, at least one dimension of the IPD is similar to at least one dimension of the integrated circuit. In an example, at least one dimension of the IPD is similar to at least one dimension of at least one memory die of the stack of memory dies. In an example, the stack of memory dies include a die attach film and wherein at least a portion of the die attach film is coupled to a top surface of the IPD. In an example, the stack of memory dies is a stack of NAND memory dies. In an example, passive components in the IPD are electrically coupled to the PCB using one or more connection points associated with the IPD.

Other examples describe a data storage device, comprising: a printed circuit board (PCB); an integrated circuit electrically coupled to the PCB; a stack of memory dies electrically coupled to the PCB; and an integrated passive device (IPD) coupled to the PCB, wherein at least a portion of the IPD acts as a spacer and supports at least a portion of the stack of memory dies. In an example, the IPD includes a plurality of connection points. In an example, the plurality of connection points are metal leads. In an example, the plurality of connection points are solder balls. In an example, at least one dimension of the IPD is similar to at least one dimension of the integrated circuit. In an example, the stack of memory dies include a die attach film and wherein at least a portion of the die attach film is coupled to a top surface of the IPD. In an example, the stack of memory dies is a stack of NAND memory dies.

Examples also describe a semiconductor package, comprising: a printed circuit board (PCB); an integrated circuit means coupled to the PCB; a spacing means coupled to the PCB, the spacing means including at least one passive component; and a stack of memory means coupled to the PCB, wherein at least a portion of one memory means of the stack of memory means is coupled to at least a portion of the spacing means. In an example, at least one passive component in the spacing means is electrically coupled to the PCB using one or more connection means associated with the spacing means. In an example, the one or more connection means are metal leads. In an example, the one or more connection means are solder balls.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features are intended to be selectively rearranged, included or omitted to produce various embodiments with a particular set of features. Having been provided with the description and illustration of the present disclosure, one skilled in the art may envision variations, modifications, and alternate aspects falling within the spirit of the broader aspects of the general inventive concept embodied in this disclosure that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a printed circuit board (PCB);
an integrated circuit electrically coupled to the PCB;
an integrated passive device (IPD) electrically coupled to the PCB; and
a stack of memory dies electrically coupled to the PCB, wherein at least a portion of one memory die of the stack of memory dies is stacked on at least a portion of the IPD causing the IPD to act as a spacer.

2. The semiconductor package of claim 1, wherein the IPD is a chip-scale package (CSP) IPD.

3. The semiconductor package of claim 1, wherein the IPD is a surface mount technology (SMT) IPD.

4. The semiconductor package of claim 1, wherein the IPD is proximate to the integrated circuit.

5. The semiconductor package of claim 1, wherein at least one dimension of the IPD is similar to at least one dimension of the integrated circuit.

6. The semiconductor package of claim 1, wherein at least one dimension of the IPD is similar to at least one dimension of at least one memory die of the stack of memory dies.

7. The semiconductor package of claim 1, wherein the stack of memory dies include a die attach film and wherein at least a portion of the die attach film is coupled to a top surface of the IPD.

8. The semiconductor package of claim 1, wherein the stack of memory dies is a stack of NAND memory dies.

9. The semiconductor package of claim 1, wherein passive components in the IPD are electrically coupled to the PCB using one or more connection points associated with the IPD.

10. A data storage device, comprising:
a printed circuit board (PCB);
an integrated circuit electrically coupled to the PCB;
a stack of memory dies electrically coupled to the PCB; and
an integrated passive device (IPD) coupled to the PCB, wherein at least a portion of the IPD acts as a spacer and supports at least a portion of the stack of memory dies.

11. The data storage device of claim 10, wherein the IPD includes a plurality of connection points.

12. The data storage device of claim 11, wherein the plurality of connection points are metal leads.

13. The data storage device of claim 11, wherein the plurality of connection points are solder balls.

14. The data storage device of claim 10, wherein at least one dimension of the IPD is similar to at least one dimension of the integrated circuit.

15. The data storage device of claim 10, wherein the stack of memory dies include a die attach film and wherein at least a portion of the die attach film is coupled to a top surface of the IPD.

16. The data storage device of claim 10, wherein the stack of memory dies is a stack of NAND memory dies.

17. A semiconductor package, comprising:
a printed circuit board (PCB);
an integrated circuit means coupled to the PCB;
a spacing means coupled to the PCB, the spacing means including at least one passive component; and
a stack of memory means coupled to the PCB, wherein at least a portion of one memory means of the stack of memory means is coupled to at least a portion of the spacing means.

18. The semiconductor package of claim 17, wherein the at least one passive component in the spacing means is electrically coupled to the PCB using one or more connection means associated with the spacing means.

19. A The semiconductor package of claim 18, wherein the one or more connection means are metal leads.

20. The semiconductor package of claim 18, wherein the one or more connection means are solder balls.
